(19) United States
(12) Patent Application Publication
(10) Pub. No.: US 2006/0051889 A1
(43) Pub. Date: Mar. 9, 2006

(54) Chip assembly reinforcement

(76) Inventor: Vinu Yamunan, Austin, TX (US)

Correspondence Address: TEXAS INSTRUMENTS INCORPORATED, P O BOX 655474, M/S 3999, DALLAS, TX, 75265, US

(21) Appl. No.: 10/935,842

(22) Filed: Sep. 8, 2004

(51) Int. Cl. H01L 21/44

(52) U.S. Cl. 438/106

(57) ABSTRACT

Reinforced IC assemblies and methods useful for manufacturing the same are described. A reinforced IC assembly has a mounting surface for receiving a semiconductor die and a semiconductor die affixed to the mounting surface with an underfill material interposed between the mounting surface and the semiconductor die. Fillet material reinforces the junction of the die and the mounting surface. The underfill material and the fillet material have compatible chemistries for forming a strong bond. Preferably, a underfill material having a relatively low viscosity is used, and fillet material having a relatively high viscosity is used. Exemplary embodiments of the invention are described in which a base material is used as the basis for both the underfill material and the fillet material; the base material is modified with an additive to form the fillet material.

### TECHNICAL FIELD

The invention relates to a semiconductor devices. More particularly, the invention relates to semiconductor device assemblies and methods for manufacturing the same.

### BACKGROUND OF THE INVENTION

Problems are encountered with packaged semiconductor devices used in the arts both in the manufacturing stages and in testing and use. Among the problems, some of the most common and debilitating are cracks in, and the separation of, layers of devices and open or short circuits caused by separation of materials or the ingress of moisture between separated or partially separated materials. Attempts to improve the bond between semiconductor dies and mounting surfaces have been made by using underfill material sandwiched between a die and a mounting surface such as a printed circuit board (PCB), and fillets at the edges of the die. The underfill material is intended to provide a strong bond between the surfaces, and the fillets are intended to further reinforce the mechanical strength of the die-to-PCB structure. Nevertheless, mechanical stresses in chip assemblies can lead to cracks in underfill or fillet material. Voids can sometimes form during the placement of the underfill material, and can make the chip assembly particularly susceptible to cracking under mechanical stress. Especially in large die applications, high viscosity underfill materials present difficulties in achieving void-free, one hundred percent coverage. In addition, high viscosity underfill materials require a relatively long application time in order to completely fill a large die area. Commonly used underfilling techniques encounter further difficulties due to incompatible material properties. Material compatibility is required in order to ensure a strong bond between the underfill material and the adjacent materials. Fillets constructed using techniques known in the arts also encounter difficulties due to incompatibility of materials. Due to the geometry of fillets, high viscosity materials are generally more desirable than low viscosity materials. This is in conflict with viscosity requirements for underfill materials, generally preventing the use of identical materials for both underfill and fillets, which may further complicate meeting material compatibility requirements.

Due to these and other problems, improved semiconductor chip reinforcement and methods for manufacturing improved underfill layers and fillets would be useful and advantageous in the arts.

### SUMMARY OF THE INVENTION

In carrying out the principles of the present invention, in accordance with preferred embodiments thereof, reinforced IC assemblies and methods useful for manufacturing the same are provided.

According to one aspect of the invention, a reinforced IC assembly has a mounting surface for receiving a semiconductor die. A semiconductor die is affixed to the mounting surface with an underfill material interposed between the mounting surface and the semiconductor die. Fillet material reinforces the junction of the die and the mounting surface. The underfill material and the fillet material have compatible chemistries for forming a strong bond.

According to another aspect of the invention, a reinforced IC assembly includes underfill material having a relatively low viscosity.

According to yet another aspect of the invention, a reinforced IC assembly includes fillet material having a relatively high viscosity.

According to still another aspect of the invention, methods of reinforcing an IC assembly include steps for placing underfill material between a mounting surface and a semiconductor die, operably mounting the die on the mounting surface, and placing fillet material at the junction of the die and the mounting surface. The underfill material and the fillet material are selected for having compatible chemistries for forming a reinforcing bond at the junction.

According to another aspect of the invention, steps are included for selecting a base material for use as the basis for both the underfill material and the fillet material and modifying the base material to form the fillet material.

The invention has numerous advantages including but not limited to providing high throughput processes and highly reliable chip assemblies. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cut-away side view of an example of a preferred embodiment of the invention; and

FIG. 2 is a top side perspective partial cut-away view of an example of a preferred embodiment of the invention.

References in the detailed description correspond to like references in the figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention provides chip assemblies having reinforced underfills and fillets and methods for manufacturing the same. Examples of preferred IC assemblies 10 embodying the invention are shown and described in which low viscosity, low modulus underfill material 12 is dispensed under the die 14 to facilitate coverage approaching one hundred percent and high throughput. Edge fillets 16 are manufactured using a suitably compatible fillet material 18 having a relatively high modulus.

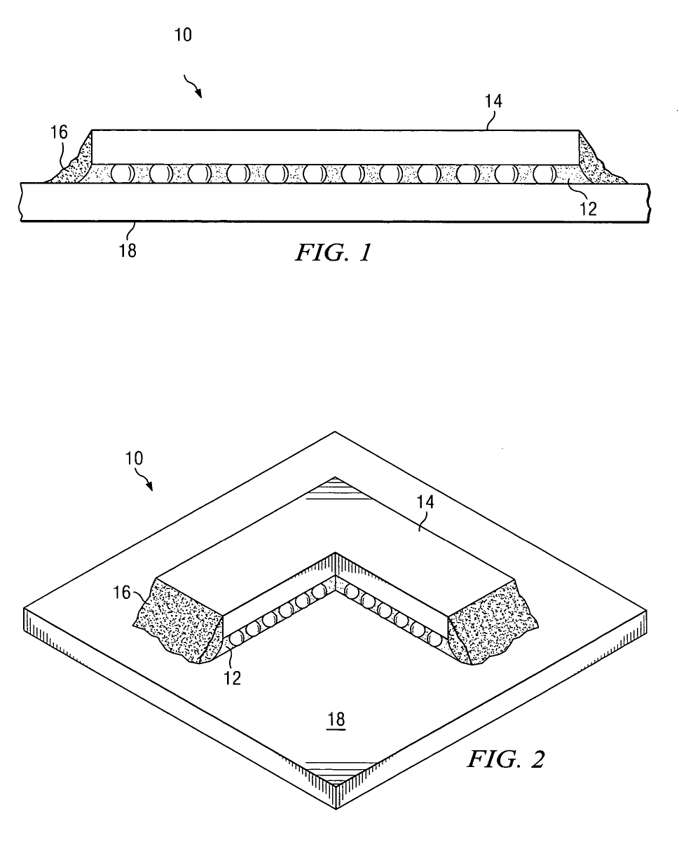

Referring to FIGS. 1 and 2, an example of a preferred embodiment of a reinforced chip assembly 10 according to the invention is shown. An underfill material 12 is disposed between a die 14 and a mounting surface 18 such as a leadframe or prepared PCB. A fillet material 16 is applied to the edges of the die 14 in order to reinforce the mounted die 14 against shearing forces. It is essential that the underfill material 12 and the fillet material 16 have compatible chemistries in order to ensure that they form crosslinks or bonds across their respective surfaces. Preferably, the die underfill material 12 is selected for favorable properties such as a low filler content, low viscosity, low modulus, high coefficient of thermal expansion (CTE), and high adhesion. The fillet material 16 preferably has a relatively higher filler content, high viscosity, high modulus, a low coefficient of thermal expansion (CTE), and high adhesion. It has been found preferable to use underfill materials having a CTE within the range of about 6-25 ppm/degree C., and fillet materials within the range of about 20-80 ppm/degree C. Material viscosity may range between approximately 800-25,000 cps at 25 degrees C.

The filler material may be any low CTE particulate material that is small enough to stay in suspension or colloidal form before the material solidifies. This prevents settling of the filler due to gravity and ensures uniform distribution through the encapsulant polymer as it crosslinks. Silica and alumina are but two examples from among the many filler materials that may be used. The typical size of the particles of the filler material is on the order of approximately 0.5-10 microns in diameter. Preferably, a total proportion of filler content within the range of approximately 15-40% for the low end and 50-75% for the high end is used.

In an alternative embodiment of the invention, the same base material may be used in the formulation of the underfill material 12 and the fillet material 16. Using this approach, two variants are made from the same starting material; one having a lower filler content, for use as underfill 12 under the die 14, and the other having a higher filler content, for use in the fillets 16. This approach virtually eliminates chemical compatibility issues between the two materials 12, 16.

It should be understood that the practice of the invention is dependent only on the chemical compatibility of the materials, not their particular chemical composition, nor on the use of specific materials. For the sake of example, either acid-anhydride based, or cyano-ester based materials known in the arts may be used. The use of alternative materials is not precluded. Various materials may be used so long as the underfill material 12 and fillet material 16 are able to form secure bonds. In the practice of using the same chemical compound as a base material, but with two different formulations having different proportions of filler material, compatibility is not a problem and the actual chemical composition of the base material is not of particular concern.

It should also be appreciated by those skilled in the arts that the invention may be practiced with suitable alteration for various types of IC assemblies, such as flip-chip or wire-bond devices. For example, in wire-bond device assemblies, it is preferable to use an underfill material with a relatively high filler content and a fillet material with a lower filler content, thus preventing any crack forming at the die-substrate junction from propagating to the substrate. These and other alternative embodiments will be apparent to those reasonably skilled in the arts.

The methods and devices of the invention provide advantages including but not limited to providing for repeatable and stable underfilling and filleting, high throughput processes, and flip chip assemblies resistant to mechanical stresses. While the invention has been described with reference to certain illustrative embodiments, the methods and systems described are not intended to be construed in a limiting sense. Various modifications and combinations of the illustrative embodiments as well as other advantages and embodiments of the invention will be apparent to persons skilled in the art upon reference to the description and claims.

I claim:

1. A reinforced IC assembly comprising:
a mounting surface for receiving a semiconductor die;
a semiconductor die affixed to the mounting surface;
an underfill material interposed between the mounting surface and the semiconductor die; and
a fillet material disposed on the mounting surface and contacting the edge of the die and coming into contact with the underfill material at the junction of the die and the mounting surface;
wherein the underfill material and the fillet material have compatible chemistries for forming a strong bond at the junction of the die and the mounting surface.

2. An IC assembly according to claim 1 wherein the underfill material further comprises a material with a low filler content.

3. An IC assembly according to claim 1 wherein the fillet material further comprises a material with a high filler content.

4. An IC assembly according to claim 1 wherein the underfill material further comprises a material with a low viscosity.

5. An IC assembly according to claim 1 wherein the fillet material further comprises a material with a high viscosity.

6. An IC assembly according to claim 1 wherein the underfill material further comprises a material with a low modulus.

7. An IC assembly according to claim 1 wherein the fillet material further comprises a material with a high modulus.

8. An IC assembly according to claim 1 wherein the underfill material further comprises a material with a low coefficient of thermal expansion.

9. An IC assembly according to claim 1 wherein the fillet material further comprises a material with a high coefficient of thermal expansion.

10. A method of reinforcing an IC assembly comprising:
placing underfill material between a mounting surface for receiving a semiconductor die and a semiconductor die;
operably mounting the die on the mounting surface;
placing fillet material on the mounting surface and contacting the edge of the die and coming into contact with the underfill material at the junction of the die and the mounting surface;
wherein the underfill material and the fillet material are selected for having compatible chemistries for forming a reinforcing bond at the junction of the die and the mounting surface.

11. A method according to claim 10 further comprising selecting an underfill material having a low filler content.

12. A method according to claim 10 further comprising selecting a fillet material having a high filler content.

13. A method according to claim 10 further comprising selecting an underfill material having a low viscosity.

14. A method according to claim 10 further comprising selecting a fillet material having a high viscosity.

15. A method according to claim 10 further comprising selecting an underfill material having a low modulus.

16. A method according to claim 10 further comprising selecting a fillet material having a high modulus.

17. A method according to claim 10 further comprising selecting an underfill material having a low coefficient of thermal expansion.

18. A method according to claim 10 further comprising selecting a fillet material having a high coefficient of thermal expansion.

19. A method according to claim 10 further comprising steps of:
selecting a base material for use as the basis for both the underfill material and the fillet material; and
modifying the base material to form the fillet material.

20. A method according to claim 19 wherein the modifying step further comprises increasing the filler content.
